(19) United States
(12) Patent Application Publication
(10) Pub. No.: US 2026/0074148 A1
(43) Pub. Date: Mar. 12, 2026

(54) SOLID STATE VARIABLE IMPEDANCE DEVICE AND RF SOURCE SYSTEM

(71) Applicant: Applied Materials, Inc., Santa Clara, CA (US)

(72) Inventors: DAVID COUMOU, Webster, NY (US); CHRISTOPHER OWEN, Chandler, AZ (US)

(21) Appl. No.: 19/195,641

(22) Filed: Apr. 30, 2025

Related U.S. Application Data
(60) Provisional application No. 63/692,637, filed on Sep. 9, 2024.

(51) Int. Cl. H01J 37/32; H03H 11/28; H03K 17/687

(52) U.S. Cl. CPC H01J 37/32183; H03H 11/28; H03K 17/6871

(57) ABSTRACT

Embodiments described herein relate to an apparatus that includes an electrically conductive path and switched shunt capacitor electrically coupled to the electrically conductive path. In an embodiment, the switched shunt capacitor is configured to be switched on and off by a half-bridge circuit that includes a first transistor and a second transistor, and wherein an RF choke is on an electrical path between the first transistor and the second transistor.

### CROSS-REFERENCE TO RELATED APPLICATIONS

This application claims the benefit of U.S. Provisional Application No. 63/692,637, filed on Sep. 9, 2024, the entire contents of which are hereby incorporated by reference herein.

### BACKGROUND

### 1) Field

Embodiments of the present disclosure pertain to the field of plasma systems that include a multi-stage solid state impedance match.

### 2) Description of Related Art

In plasma processing tools (e.g., plasma etching chambers, plasma deposition chambers, plasma treatment chambers, etc.), precise control of the source power delivered to the chamber is needed to control the efficiency for the plasma system and prevent damage from reflected power back to the power source. Impedance matching is one parameter that is useful for controlling the power delivered to the chamber. For example, an impedance match is used to match the impedance of the power delivery system to the load impedance within the chamber.

Existing impedance match solutions include electro-mechanical devices and solid-state devices. Electro-mechanical devices are useful for high power applications, but they do not allow for rapid adjustments due to the use of a mechanical motor that is orders of magnitude slower than the ion transition rates across a plasma sheath. Solid state devices provide improved speed but are limited in voltage and/or current handling capability. Solid state devices also suffer from poor resolution.

### SUMMARY

Embodiments described herein relate to an apparatus that includes an electrically conductive path and switched shunt capacitor electrically coupled to the electrically conductive path. In an embodiment, the switched shunt capacitor is configured to be switched on and off by a half-bridge circuit that includes a first transistor and a second transistor, and wherein an RF choke is on an electrical path between the first transistor and the second transistor.

Embodiments described herein relate to an apparatus that includes an RF generator, and an impedance match electrically coupled to the RF generator. In an embodiment, the impedance match includes a bank of switched shunt capacitors that are each configured to be controlled by a corresponding one of a plurality of circuits, wherein each of the plurality of circuits includes a transistor with a bandgap of at least 1.5 eV.

Embodiments described herein relate to a varactor that includes a first transistor with a first gate that is configured to be grounded, and a second transistor with a second gate that is configured to be grounded. In an embodiment, the varactor further includes a first inductor electrically coupled to a first drain of the first transistor, a second inductor electrically coupled to a second drain of the second transistor, and a voltage source electrically coupled between the first inductor and the second inductor. In an embodiment, at least one of the first transistor or the second transistor includes a bandgap that is at least 1.5 eV.

### BRIEF DESCRIPTION OF THE DRAWINGS

FIG. 1A is a schematic illustration of a multi-stage match that includes banks of switched shunt capacitors that are controlled by high bandgap transistor devices, in accordance with an embodiment.

FIG. 1B is a schematic illustration of a multi-stage match that includes banks of switched shunt capacitors that are controlled by high bandgap transistor devices that includes a sensor at a power output of the match, in accordance with an embodiment.

FIG. 1C is a schematic illustration of a plasma processing tool that comprises a power generator, a multi-stage solid state impedance match, and a plasma chamber, in accordance with an embodiment.

FIG. 2A is a schematic illustration of a second stage of an impedance match with a pair of capacitor banks, in accordance with an embodiment.

FIG. 2B is a schematic illustration of a first stage of an impedance match with a set of three capacitor banks, in accordance with an embodiment.

FIG. 2C is a circuit diagram of an individual switched shunt capacitor that is controlled by a high bandgap transistor, in accordance with an embodiment.

FIG. 2D is a circuit diagram of an individual switched shunt capacitor that is controlled by a pair of transistors arranged in a half-bridge configuration, in accordance with an embodiment.

FIG. 3A is a circuit diagram of a varactor that is implemented with high bandgap transistors, in accordance with an embodiment.

FIG. 3B is a circuit diagram of a varactor with an alternative construction, in accordance with an embodiment.

FIG. 4A is a schematic illustration of an RF generator that comprises an autotransformer with taps for making a coarse impedance adjustment before the power is delivered to a multi-stage match, in accordance with an embodiment.

FIG. 4B is a circuit diagram of an auto-transformer with taps that is driven by a plurality of high bandgap transistors, in accordance with an embodiment.

FIGS. 5A and 5B are schematics of a switched impedance transformer with an open and closed shunt MOSFET that switches to ground, in accordance with an embodiment.

FIG. 5C is a schematic of a switched impedance transformers that are in series and parallel to produce equivalent series and parallel capacitors, in accordance with an embodiment.

FIG. 6A is a schematic of an auto transformer with a switched capacitor that is used as a series capacitor, in accordance with an embodiment.

FIG. 6B is a schematic of a plurality of auto transformers with switched capacitors that are coupled in parallel to reduce peak transformer current and capacitor voltage, in accordance with an embodiment.

FIG. 7A is a schematic illustration of an impedance matching system with a first switched shunt capacitor on the input RF line to the load and a second switched shunt capacitor on a return RF line from the load, in accordance with an embodiment.

FIG. 7B is a schematic illustration of an impedance matching system with a first switched shunt capacitor on the input RF line to the load and a bank of second switched shunt capacitors with auto transformers on a return RF line from the load, in accordance with an embodiment.

FIG. 8 is an illustration of a block diagram of an exemplary computer system that may be used in conjunction with a processing tool, in accordance with an embodiment.

### DETAILED DESCRIPTION

Plasma systems that include a multi-stage solid state impedance match are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, impedance matches provide the control that enables efficient power delivery to plasma processing tools (e.g., plasma etching chambers, plasma deposition chambers, plasma treatment chambers, etc.). In order to provide the high switching speed needed for many plasma processes, solid state impedance matches have become a popular option. However, the low voltage limitations, low current handling capability, and/or poor resolution of existing solid-state options render such systems not suitable for high power environments.

Accordingly, embodiments disclosed herein may include solid state impedance matches that are based on high bandgap transistor devices. For example, high bandgap transistors (also sometimes referred to as wide bandgap transistors) may have a bandgap in the range of approximately 1.5 eV to approximately 4.0 eV or higher. In a particular embodiment, silicon carbide (SiC) transistors may be used in order to switch capacitors on and off in order to modify an impedance of the power delivery network. SiC transistor devices provide low RDSon, low parasitic capacitances (Coss), and may include VA ratings suitable for use in high-power RF networks. While SiC transistors are included as one option herein, it is to be appreciated that any suitable high bandgap transistor may be used, such as a GaN transistor, other III-V group semiconductor transistors, or the like. These high bandgap transistors enable the use of a broad capacitance range with optimized switching characteristics and faster stabilization of plasma generation. This allows for improved performance in a cost effective manner.

In some instances, the DC bias voltages used to vary the capacitance of a cell arrangement of diodes are limited by the rise time of the DC power supply. The current draw for the DC power is a function of the rise time. A low current may be used to reverse bias the diodes in some of the embodiments disclosed herein. This allows for a DC power rise time that is approximately 10 us or less or approximately 1.0 us or less. Such fast switching speeds may lead to significantly expanded process regimes for the plasma processing tool. The fast switching may also provide new tool capabilities for the control of plasma loads in the semiconductor industry. Faster switching times also speed up process times and reduces the total energy consumed by the process.

In an embodiment, the solid-state match may comprise a multi-stage matching network. In some embodiments, the multi-stage matching network may include a first matching network and a second matching network. In some instances, cascaded stages are implemented to adjust impedance transformation. Coupling between stages allows for minimization of losses while maximizing power efficiency by tailoring parasitic coupling and resistive losses from solid-state devices. Though, it is to be appreciated that embodiments disclosed herein may also be practiced with a single stage. In an embodiment, the solid-state impedance tuning system may be integrated with an RF power amplifier for unified power compensation and impedance control. This allows for optimal load power control for plasma stability through a wide dynamic impedance variation during plasma ignition and multi-rate pulsing. In some embodiments, the match may also provide harmonic attenuation. This allows for a reduction in the complexity of an RF generator harmonic filter. Additionally, high Q components can be used. This allows for greater reduction in RF losses, which is particularly beneficial for low plasma load impedances.

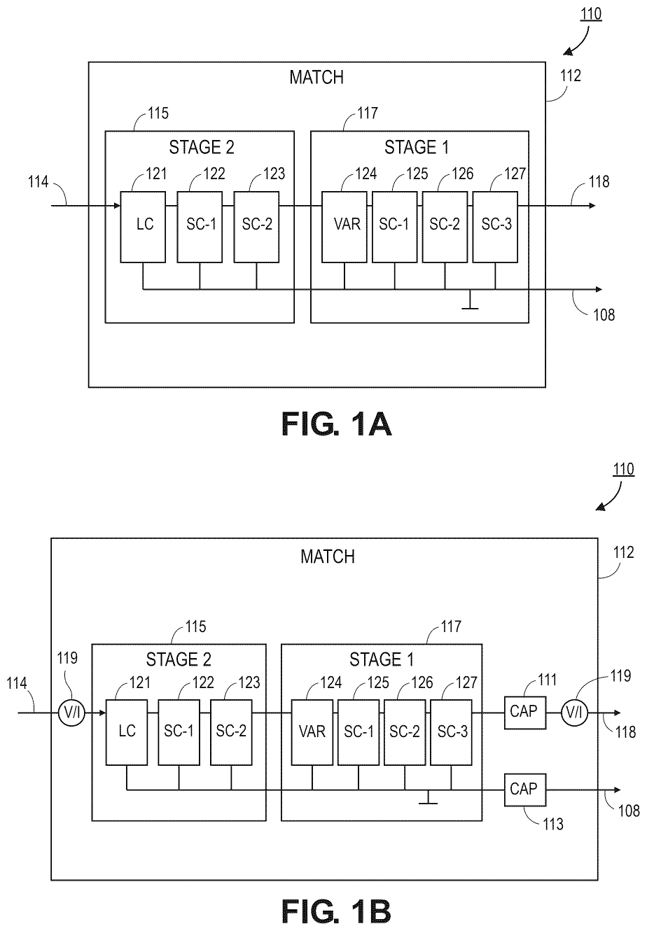

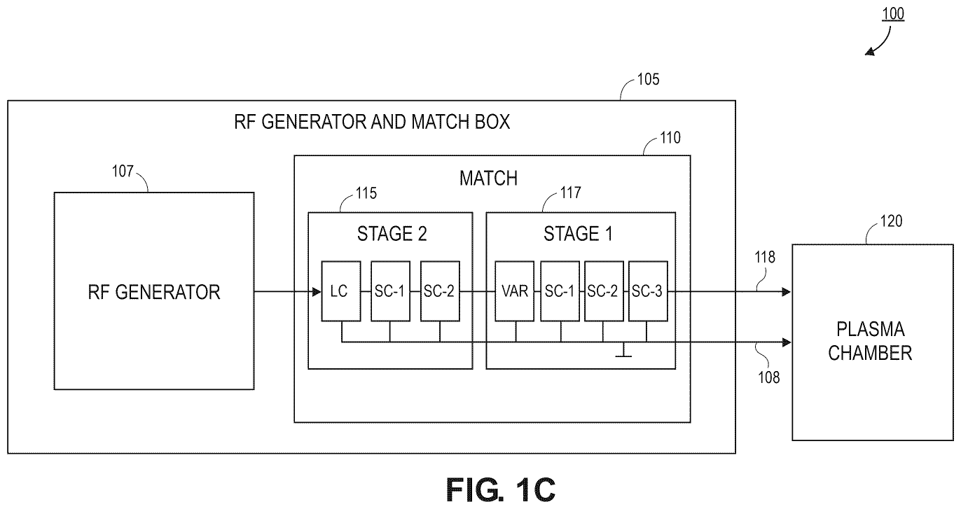

Referring now to FIG. 1A, a schematic illustration of an impedance match 110 is shown, in accordance with an embodiment. In an embodiment, the impedance match 110 may be an RF impedance match. For example, an RF generator (not shown) may provide RF power to an input 114 of the impedance match 110. Similarly, impedance matched power may exit the impedance match 110 at output 118. A ground line 108 may also be coupled to the impedance match 110.

In an embodiment, the impedance match 110 may comprise a board 112 for mounting one or more impedance matching stages. For example, a second stage 115 may be electrically coupled to the input 114, and a first stage 117 may be electrically coupled to the output 118. In the illustrated embodiment, the first stage 117 and the second stage 115 are provided on separate boards. Though, the first stage 117 and the second stage 115 may also be on the same board in some embodiments. Additionally, while two stages 117 and 115 are shown in FIG. 1A, it is to be appreciated that one or more stages may also be used in some embodiments. That is, the number of stages is scalable to fit the needs of a desired application.

In an embodiment, the second stage 115 may include an LC module 121 (e.g., a circuit element comprising one or more capacitors and one or more inductors). The LC module 121 may feed into a first switched shunt capacitor bank 122 and a second switched shunt capacitor bank 123. While shown in FIG. 1A, other embodiments may omit the LC module 121. In an embodiment, the switched shunt capacitor banks 122 and 123 may each comprise a plurality of switched shunt capacitors that are each turned on/off through the use of high bandgap transistors, such as a SiC transistor or the like. A more detailed explanation of the switched shunt capacitors will be provided in greater detail herein.

While a first switched shunt capacitor bank 122 and a second switched shunt capacitor bank 123 are shown in FIG. 1A, it is to be appreciated that any number of switched shunt capacitor banks may be used in the second stage 115. Each of the switched shunt capacitor banks 122 or 123 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

In an embodiment, the second stage 115 may be used to convert an impedance of the power delivery network to match an impedance of an RF generator (not shown). For example, the impedance of the RF generator may be approximately 50 Ohms. In an embodiment, the first stage 117 may be used to match the impedance of the load coupled to the power delivery network (e.g., a plasma within a chamber coupled to the impedance match 110).

In an embodiment, the first stage 117 may be electrically coupled to the second stage 115. The first stage 117 may comprise a varactor 124 and a plurality of additional switched shunt capacitor banks 125, 126, and 127. The varactor 124 may allow for an analog (i.e., substantially continuous) control of the impedance before reaching the additional switched shunt capacitor banks 125, 126, and 127. While shown as being within the first stage 117, other embodiments may include inserting the varactor 124 in the second stage 115 (e.g., before the switch shunt capacitor banks 122 and 123) or as a discrete system between the first stage 117 and the second stage 115. In an embodiment the varactor 124 may also be implemented as a solid state component. In such an embodiment, the varactor 124 may comprise high bandgap transistors, such as SiC transistors. A more detailed explanation of the varactor 124 is provided below.

In an embodiment, the first stage 117 may be used to control an impedance from between approximately 0.2 Ohms to approximately 10 Ohms in order to match a load impedance within a plasma chamber that is electrically coupled to the output 118. Further, the first stage 117 may be used to transfer the whole range of complex load impedances to a purely resistive impedance for the desired range (e.g., approximately 0.2 Ohms to approximately 10 Ohms).

While three different switched shunt capacitor banks 125, 126, and 127 are shown in FIG. 1A, it is to be appreciated that any number of switched shunt capacitor banks may be used in the first stage 117. Each of the switched shunt capacitor banks 125, 126, and 127 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

Referring now to FIG. 1B, a plan view illustration of an impedance match 110 is shown, in accordance with an additional embodiment. In an embodiment, the impedance match 110 in FIG. 1B may be similar to the impedance match 110 in FIG. 1A, with the addition of capacitors 111 and 113. The capacitors 111 and 113 may by extremely high Q components in order to improve performance of the match 110 in some embodiments. For example, the capacitors 111 and 113 may be vacuum capacitors. In some embodiments, one or both of capacitors 111 or 113 may be optional. Additionally, an RF sensor 119 (e.g., a voltage/current (V/I) sensor) may be provided on the impedance match 110. Particularly, a pair of RF sensors 119 are provided in FIG. 1B. A first RF sensor 119 may be provided before the second stage 115 at the input 114, and a second RF sensor 119 may be provided after the first stage 117 at the output 118. In an embodiment, the RF sensors 119 may be used in order to monitor the power delivered to the plasma chamber through the impedance match 110. This can be used for control purposes and/or for an indication of when a safe operating area (SOA) is exceeded for the impedance match 110 and/or the plasma processing tool in general.

Referring now to FIG. 1C, a schematic diagram of a plasma processing system 100 is shown, in accordance with an embodiment. In an embodiment, the plasma processing system 100 may comprise an RF generator and match box 105. The box 105 may be a housing and/or enclosure that integrates an RF generator 107 and the match 110 into a single system. The RF generator 107 may generate RF power that is delivered to a plasma chamber 120 through the match 110. In an embodiment, the match 110 may be similar to the match 110 described with respect to FIG. 1A or 1B. For example, the match 110 may comprise a plurality of stages (e.g., a first stage 117 and a second stage 115). Each of the stages 117 and 115 may comprise a plurality of switched shunt capacitor banks.

In an embodiment, the plasma chamber 120 may be chamber capable of supporting a plasma. For example, the plasma chamber 120 may be a low-pressure chamber, such as a vacuum chamber. In an embodiment, the plasma chamber 120 may include a plasma deposition chamber, a plasma etching chamber, a plasma treatment chamber, or the like. The output 118 may deliver RF power to the plasma chamber 120 in order to ignite and/or sustain a plasma within the plasma chamber 120. A ground line 108 may also be coupled between the plasma chamber 120 and the match 110.

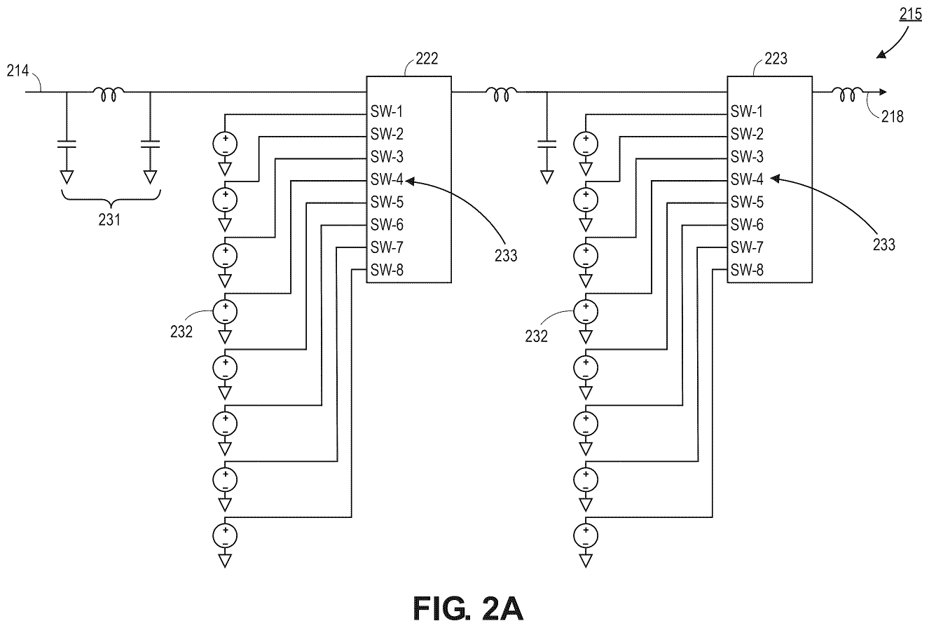

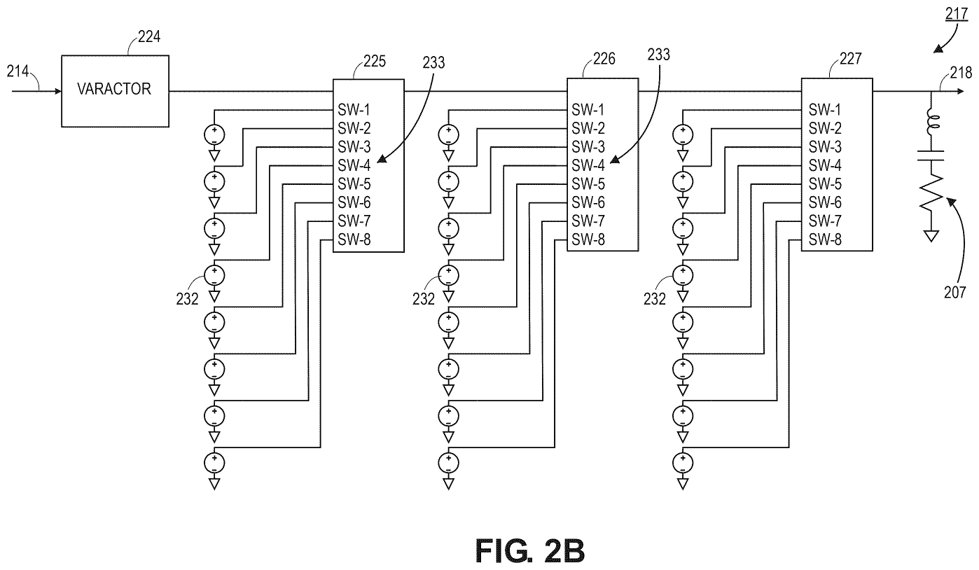

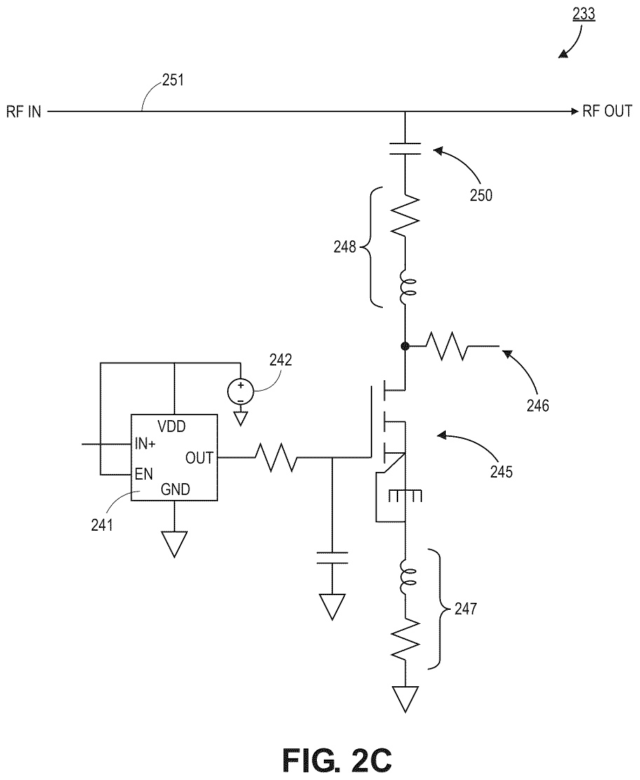

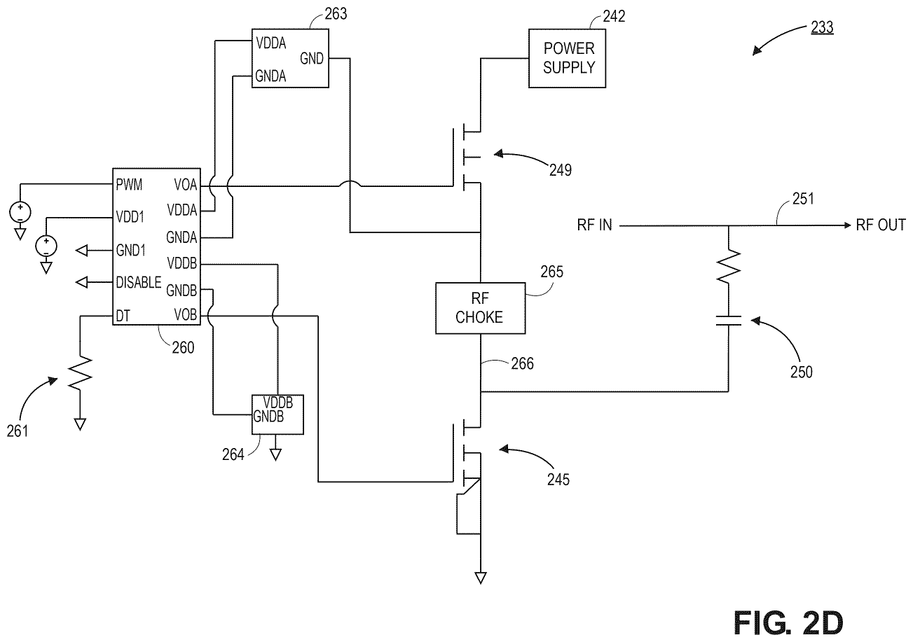

Referring now to FIGS. 2A and 2B, schematic illustrations of different stages of a multi-stage match are shown, in accordance with an embodiment. Referring now to FIG. 2A, a second stage 215 is shown, in accordance with an embodiment. As shown, an input 214 to the second stage 215 may enter an LC module 231. In an embodiment, the LC module 231 may be a circuit element comprising one or more capacitors and one or more inductors. Though, in other embodiments, the LC module 231 may be omitted. In an embodiment, the second stage 215 may continue along the main RF path to a first switched shunt capacitor bank 222 and a second switched shunt capacitor bank 223 before reaching an output 218. In an embodiment, the capacitor banks 222 and 223 each include a plurality of individual switched shunt capacitors 233. The switched shunt capacitors 233 may each be coupled to a power source 232, such as a DC power source. A more detailed description of the circuitry for the switched shunt capacitors 233 and how they are turned on/off is provided in greater detail herein.

In the illustrated embodiment, the first capacitor bank 222 and the second capacitor bank 223 have the same number of switched shunt capacitors 233. Though, in other embodiments, the capacitor banks 222 and 223 may have a different number of switched shunt capacitors 233. While eight switched shunt capacitors 233 are shown in each capacitor bank 222 and 223, it is to be appreciated that each capacitor bank 222 and 223 may comprise one or more switched shunt capacitors 233. In an embodiment, each of the switched shunt capacitors 233 may have substantially the same electrical characteristics (e.g., capacitance, Q-value, etc.). In such an embodiment, switching on a desired number of switched shunt capacitors 233 within a capacitor bank 222 or 223 can provide a desired total capacitance to the second stage 215 that is an integer multiple of the capacitance of each switched shunt capacitors 233. In some embodiments, a more granular change in the total capacitance may be provided by including switched shunt capacitors with multiple different capacitances. For example, a first switched shunt capacitor 233 may have a capacitance C, a second switched shunt capacitor 233 may have a capacitance C/2, a third switched shunt capacitor 233 may have a capacitance C/4, a fourth switched shunt capacitor 233 may have a capacitance C/8, or the like. Accordingly, more granular control of the total capacitance can be provided to the second stage 215 of the impedance match.

Referring now to FIG. 2B, a schematic illustration of a first stage 217 of the match is shown, in accordance with an embodiment. In an embodiment, the input 214 may lead into a varactor 224. The varactor 224 may provide a more granular control (e.g., analog or substantially continuous control) of the impedance. The following components may include a third capacitor bank 225, a fourth capacitor bank 226, and a fifth capacitor bank 227. In an embodiment, each of the additional capacitor banks 225-227 may be similar to the capacitor banks 222 and 223 described with respect to FIG. 2B. For example, each capacitor bank 225-227 may comprise one or more switched shunt capacitors 233 that are powered by power sources 232 (e.g., a DC power source 232). While three capacitor banks 225-227 are shown, it is to be appreciated that any number capacitor banks 225-227 may be included in the first stage 217. In some embodiments, a grounded inductor (e.g., a shunt inductor) (not shown) may be provided at the output 218 after the capacitor bank 227 in order to neutralize leakage through the match when all of the capacitors 233 are switched off. In some embodiments a second harmonic trap circuit 207 may also be provided between the last capacitor bank 227 and the output 218. The second harmonic trap circuit 207 may be used to mitigate second harmonic levels within the system. This may occur because each of the switching transistors that control the capacitors 233 have different Coss capacitance depending on whether the instantaneous drain voltage is at a high voltage or a low voltage. As such, a sine wave picks up some second harmonic distortion at each switched capacitor when the associated transistor is off. In the embodiment shown in FIG. 2B, the second harmonic trap circuit 207 comprises a shunt LC notch.

Referring now to FIG. 2C, a circuit diagram of an individual switched shunt capacitor 233 is shown, in accordance with an embodiment. In an embodiment, the switched shunt capacitor 233 may comprise a capacitor 250 that is coupled to a main RF line 251. In an embodiment, the capacitor 250 is switched from on to off through the use of a transistor 245. In an embodiment, the transistor 245 may comprise a high bandgap transistor, such as one formed with SiC, GaN, other III-V group semiconductor transistors, or the like. For example, the transistor 245 may comprise a SiC MOSFET device. The power for the transistor 245 may be provided by a power supply 242 (e.g., a DC power supply 242) that is coupled to a PWM driver 241. In an embodiment, a high voltage bias branch 246 may be provided between the transistor 245 and the capacitor 250. The high voltage bias branch 246 may comprise a high voltage power source (not shown), such as a high voltage DC power source. In an embodiment, some parasitic elements 247 and 248 are illustrated in the circuit for illustration purposes.

Referring now to FIG. 2D, a circuit diagram of an individual switched shunt capacitor 233 is shown, in accordance with an additional embodiment. The switched shunt capacitor 233 in FIG. 2D may be driven with a half-bridge topology. For example, a pullup transistor 249 and a pulldown transistor 245 may be used to charge and discharge the capacitor 250. The pullup transistor 249 and the pulldown transistor 245 may be high bandgap transistors, such as SiC transistors, GaN transistors, other III-V group semiconductor transistors, or the like. The source of the pulldown transistor 245 may be coupled to ground, and the drain of the pullup transistor 249 may be coupled to a power supply 242. The power supply 242 may be a DC power supply.

In an embodiment, a source of the pullup transistor 249 may be electrically coupled to a drain of the pulldown transistor 245 by an electrical trace 266. An RF choke circuitry block 265 may be provided along the electrical trace 266. The RF choke circuitry block 265 may prevent RF propagation into the pullup transistor 249. The RF choke circuitry block 265 may include one or more RF filter circuits, inductors, and/or the like.

In an embodiment, the pullup transistor 249 and the pulldown transistor 245 may be driven by a half-bridge driver 260. The half-bridge driver 260 may have a resistor 261 coupled to the DT input to ensure that the pullup transistor 249 and the pulldown transistor 245 are not on at the same time. The resistor 261 may be chosen to provide a dead time that is approximately 0.5 μs or less.

In an embodiment, the half-bridge driver 260 may be coupled to a first power supply 263 for controlling the pullup transistor 249. That is, the first power supply 263 may be electrically coupled to the gate of the pullup transistor 249 through the half-bridge driver 260. The first power supply 263 may be held at an electrically floating voltage set by the power supply 242 (e.g., around 600V). Since the first power supply 263 is electrically floating, the first power supply 263 is capable of pulling up the voltage to block RF current from going into the pullup transistor 249. The half-bridge driver 260 may also be coupled to a second power supply 264 for controlling the pulldown transistor 245. That is, the second power supply 264 may be electrically coupled to the gate of the pulldown transistor 245 through the half-bridge driver 260. The half-bridge driver 260 allows for voltage to be applied to either the gate of the pullup transistor 249 (which allows power supply 242 to charge the capacitor 250) or to the gate of the pulldown transistor 245 (which allows the charge in the capacitor 250 to be drained to ground).

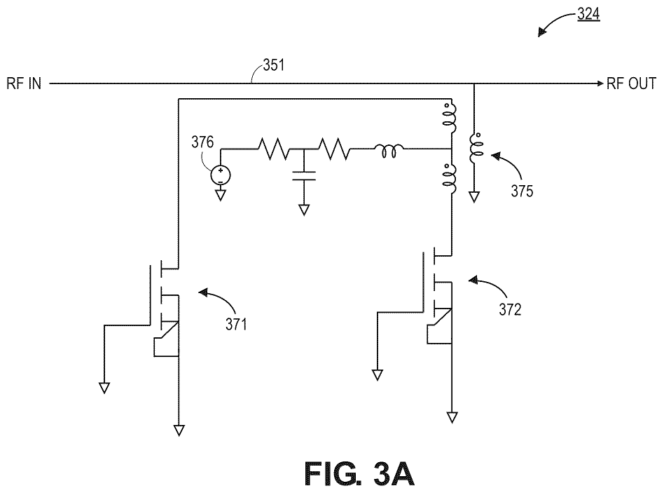

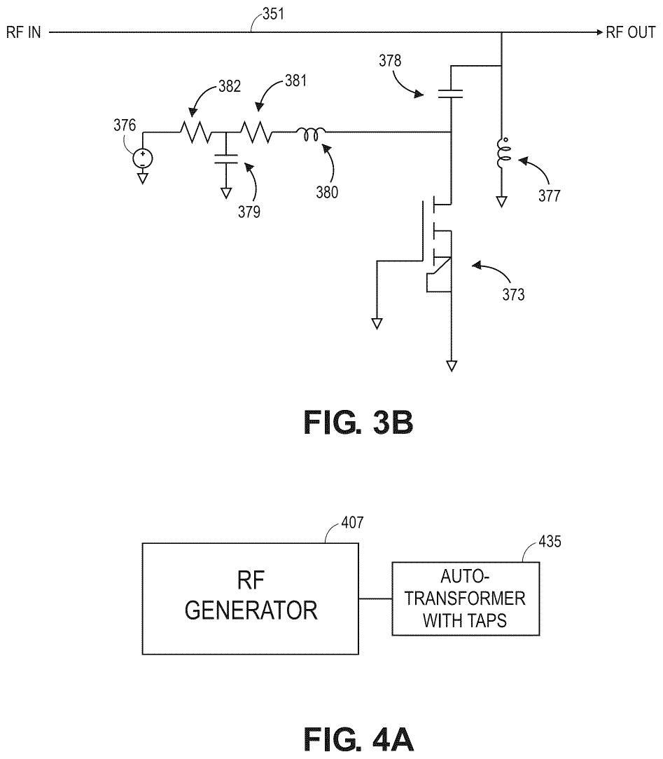

Referring now to FIGS. 3A and 3B, a pair of circuit diagrams of different varactors 324 are shown, in accordance with various embodiments. In an embodiment, the varactors 324 may be included as part of an impedance match, such as any of those described herein. For example, the varactor 324 in FIGS. 3A and 3B may be used in the first stage 117 of the impedance match 110 in FIGS. 1A-1C. Though, it is to be appreciated that solid state varactor architectures similar to those described with respect to varactors 324 may be used for any purpose. In an embodiment, a bias voltage sweep may be applied to the varactor 324 in order to provide a variable capacitance value to the attached circuit. For example, the varactors 324 may be coupled to an RF line 351 of an RF match or the like.

In the embodiment shown in FIG. 3A, the varactor 324 may be a balanced varactor. For example, a balanced transformer 375 is coupled to a first transistor 371 and a second transistor 372. In some embodiments, one or both of the first transistor 371 and the second transistor 372 may be high bandgap transistors, such as SiC transistors, GaN transistors, other III-V group semiconductor transistors, or the like. The gate voltages of both the first transistor 371 and the second transistor 372 may be grounded to ensure that both transistors 371 and 372 are fully turned off. As such, the only RF current flowing through the varactor 324 is due to the Coss capacitance of each transistor 371 and 372. A voltage source 376 of the varactor 324 can be swept (e.g., between 200V and 400V) in order to produce a variable capacitance that is applied to the RF line 351.

In the embodiment shown in FIG. 3B, the varactor 324 may be a single ended varactor 324. That is, a single transistor 373 with a grounded gate may be used. The single transistor 373 may be electrically coupled to the RF line 351 with a fixed value capacitor 378 between the single transistor 373 and the RF line 351. The voltage source 376 (that can be swept from a first voltage to a second voltage), is electrically coupled to the circuit (with the capacitor 378 between the voltage source 376 and the RF line 351). In an embodiment, a shunt capacitor 379 with resistors 382 and 381 on either side of the shunt capacitor 379, and a fixed value inductor 380 may be provided in the circuit between the voltage source 376 and the capacitor 378. In some embodiments, a grounded inductor 377 may also be electrically coupled to the RF line 351.

With respect to a varactor 324 that is used in an impedance match, such as any of those described herein, the varactor 324 may be designed in order to provide variable capacitance values in a range that is greater than the smallest switched capacitor step size. For example, the range may be up to 20 pF or more, or up to 50 pF or more. As such, the total capacitance provided to a stage of the impedance match may be varied to a single picofarad. Accordingly, improved resolution for the impedance match is provided through the use of a varactor such as varactor 324.

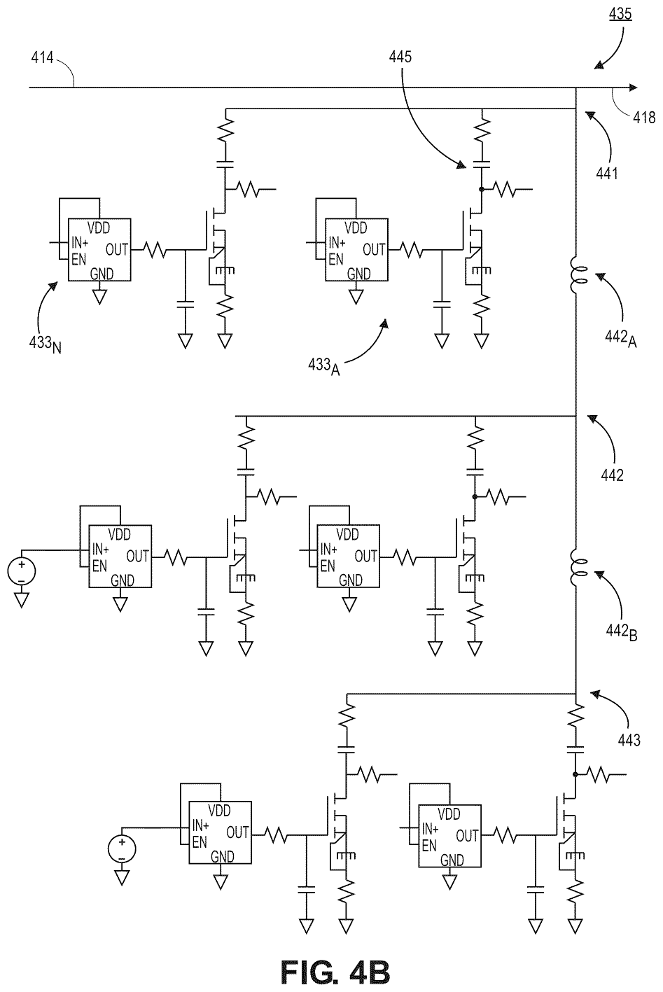

Referring now to FIG. 4A, a schematic illustration of an RF generator 407 that can be used in a plasma processing tool, such as those described herein, is shown in accordance with an embodiment. In an embodiment, the RF generator 407 may further be coupled to an auto-transformer 435 with taps. In the illustrated embodiment, the RF generator 407 and the auto-transformer 435 with taps are provided as discrete components. Though, in other embodiments, the auto-transformer 435 with taps and the RF generator 407 may be integrated together or provided within a single system. In an embodiment, a multiple tapped auto transformer design allows for a coarse impedance matching for a generator output as part of a matching system, such as those disclosed herein. Similar to other embodiments described herein, the auto-transformer may use high bandgap transistors (e.g., SiC MOSFETs) in order to provide fast switching capabilities for modifying impedance. The switched impedance may depend on fixed pre-tuned values of the auto-transformer taps, the series capacitor values being switched, as well as the transistor Rdson and Coss.

Referring now to FIG. 4B, a circuit diagram of an auto-transformer 435 with taps 445 is shown, in accordance with an embodiment. In an embodiment, the auto-transformer 435 may comprise a plurality of capacitance branches 441, 442, and 443 that are separated from each other by inductors 442A and 442B. While three capacitance branches 441-443 are shown in FIG. 4B, it is to be appreciated that any number of capacitance branches may be used to provide a desired resolution for the coarse impedance modification provided by the auto-transformer.

In an embodiment, each of the branches 441, 442, and 443 may comprise one or more circuits for switched shunt capacitors 433. For example, switched shunt capacitors 433A and 433N are shown in the branch 441. In them embodiment shown in FIG. 4B, each of the branches 441, 442, and 443 include the same number of switch shunt capacitors 433. Though, in other embodiments different numbers of switched shunt capacitors 433 may be provided within each branch 441, 442, and/or 443. The switched shunt capacitors 433 may each have circuitry similar to other switched shunt capacitors described in greater detail herein. In an embodiment, each switched shunt capacitor 433 may also have a tap 445 that allows for capacitance to be added to the main RF power delivery line between an input 414 and an output 418.

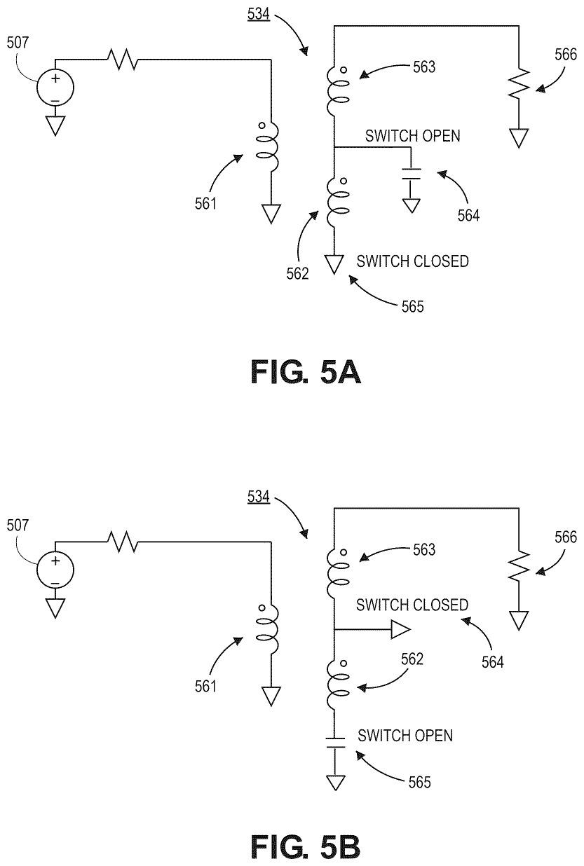

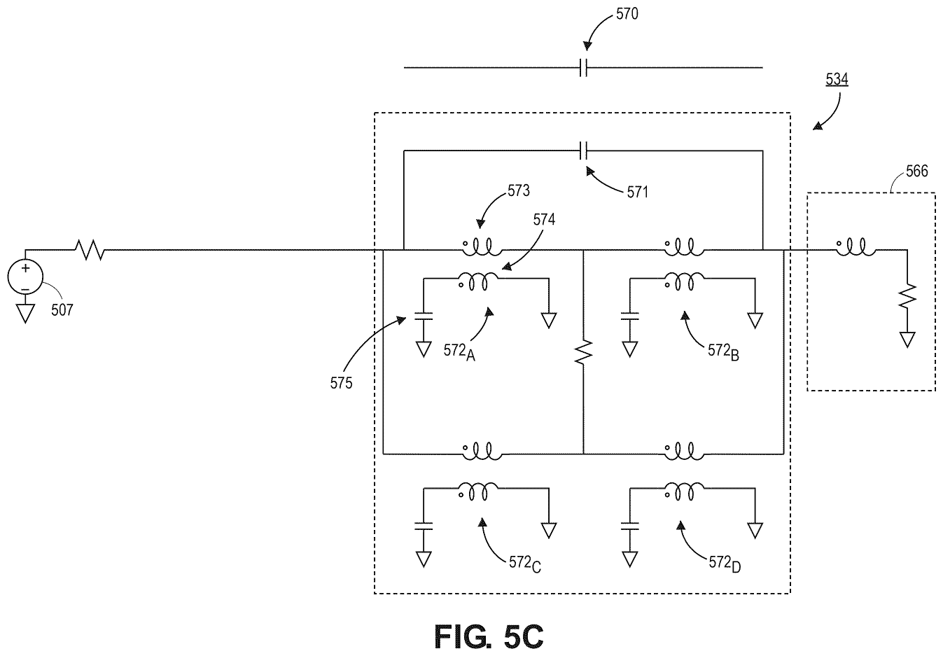

Referring now to FIGS. 5A and 5B, a pair of circuit diagrams for a switched impedance transformer 534 is shown, in accordance with an embodiment. In an embodiment, the switched impedance transformer may be used in a manner similar to auto transformers described in greater herein. For example, a switched impedance transformer 534 may be used to provide coarse impedance matching for a generator output as part of a matching system, such as those disclosed herein. Similar to other embodiments described herein, the switched impedance transformer 534 may use high bandgap transistors (e.g., SiC MOSFETs) in order to provide fast switching capabilities for modifying impedance.

As shown, the switched impedance transformer 534 may comprise a first inductor 561 (e.g., a primary winding) that is coupled to an RF generator 507 and a pair of opposing inductors 562 and 563 (e.g., a secondary winding) that are coupled to the load 566 (such as a plasma). The inductors 562, 563, and 564 may all have the same impedance in some embodiments. As shown in FIG. 5A, the inductor 562 is grounded (MOSFET switch closed) at 565, and the line electrically coupled between the inductors 562 and 563 is open (MOSFET switch open) at 564 so that a capacitance is provided to the circuit through the inductor 563. As shown in FIG. 5B, the MOSFETs are switched so that the inductor 562 is open (MOSFET switch open) at 565 so that a capacitance is provided to the circuit through the inductor 562, and the line electrically coupled between the inductors 562 and 563 is closed (MOSFET switch closed) at 564. Depending on the switch states, the transformer 534 may match the respective load impedances.

Referring now to FIG. 5C, a circuit diagram of a switched impedance transformer 534 with a plurality of transformers 572A-572p that are coupled together in series and in parallel are used to produce equivalent series and parallel capacitors. For example, the equivalent capacitance 570 is shown above the dashed box around the switched impedance transformer 534. The use of such a multi-transformer 572 architecture allows for the sharing of current, voltage, and power dissipation.

In an embodiment, the switched impedance transformer 534 may comprise a fixed capacitor 571 that is in parallel with the plurality of transformers 572A-572D. Each of the transformers 572 may comprise a first inductor 573 (e.g., second winding) and an opposing second inductor 574 (e.g., primary winding). The second inductor 574 may be electrically coupled to a switched shunt capacitor 575 (such as any of the switched shunt capacitors described herein). While a single switched shunt capacitor 575 is shown for each transformer 572, it is to be appreciated that a bank of switched shunt capacitors 575 may be used to provide a variable capacitance to the transformer 572. The RF generator 507 may be electrically coupled to the switched impedance transformer 534 through a controller (not shown), and the opposite end of the switched impedance transformer 534 may be electrically coupled to a load 566 (such as a plasma). While a switched impedance transformer 534 is described with respect to FIGS. 5A-5C, it is to be appreciated that switched impedance auto transformers may also be used in some embodiments.

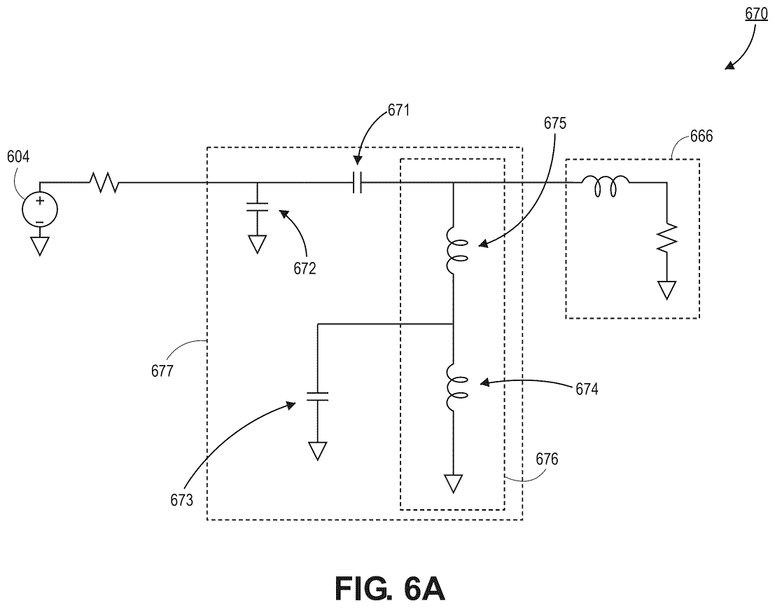

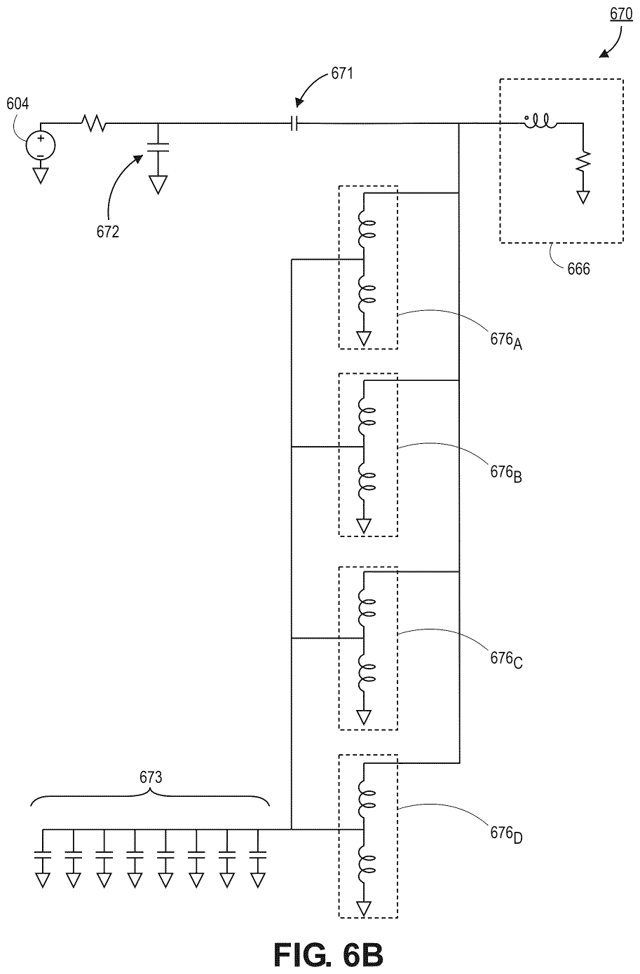

Referring now to FIG. 6A, a circuit diagram of a system 670 that includes an auto transformer 676 that may be configured as an equivalent series capacitor 677 is shown, in accordance with an embodiment. As shown, the system 670 may comprise an RF generator 604 that is electrically coupled to a load 666 through the auto transformer 676. In an embodiment, a fixed vacuum capacitor 671 and a grounded capacitor 672 may be provided in line with the auto transformer 676.

In an embodiment, a switched shunt capacitor 673 may also be electrically coupled between the inductors 674 and 675 in an auto transformer configuration. The switched shunt capacitor 673 may be similar to any of the switched shunt capacitors described in greater detail herein. Further, while shown as a single switched shunt capacitor 673, it is to be appreciated that a bank of switched shunt capacitors 673 with different capacitance values may be used to provide a desired level of capacitance to the auto transformer 676.

In an embodiment, the turns ratio between the inductors 674 and 675 may be chosen to transform a switched capacitance adjustment of about 0 pF to 3 nF into an equivalent capacitance range of approximately 0 pF to approximately 200 pF. As such, the total capacitance applied to the circuit can be the sum of the capacitance of the fixed capacitor 671 and the variable capacitance provided by the switched shunt capacitor 673 and the auto transformer 676.

Referring now to FIG. 6B, a circuit diagram of a system 670 that comprises a plurality of auto transformers 676A-676p that are arranged in parallel is shown, in accordance with an additional embodiment. Four auto transformers 676 are shown in FIG. 6B, but other embodiments may comprise two or more auto transformers connected in parallel. Providing the plurality of auto transformers 676 in parallel allows for a reduction in peak transformer current and capacitor voltage. The auto transformers 676 may be provided in series with the fixed capacitor 671. As shown, a bank of switched shunt capacitors 673 may be electrically coupled between the inductors of each transformer 676. In FIG. 6B, the auto transformers 676 are shown as being in parallel only. However, in other embodiments, the transformers 676 may be electrically coupled in series, or in both series and in parallel (e.g., similar to the conventional transformer shown in FIG. 5C). For the auto transformer embodiments, it may also be possible to fix the switched capacitance value and obtain a purely resistive match through the use of auto frequency tuning (AFT).

The use of conventional transformers and/or auto transformers with switched shunt capacitors such as those described with respect to FIGS. 5A to 6B may be used as equivalent adjustable series capacitors to rapidly compensate (e.g., within 5 μs, within 2 μs, or within 1 μs) for load inductance variations. Accordingly fast changes to plasma load inductances may be accounted for by the impedance matching system. With either the conventional transformer or the auto transformer, the impedance tuning is capable of being tuned all the way to the real axis. This is further than is needed to provide a completed match with a switched shunt capacitor and reduces the series capacitance adjustment range.

In some instances, the use of auto transformers may result in variations to the real impedance of the system. In such instances, the controller may be used to compensate for the changes to the real impedance. Additionally, while specific components are shown in FIGS. 5A-6B, other electrical components may be added at various locations within the system in order to make impedance matching easier to implement and/or to have high Q values.

Thus, embodiments of the present disclosure include systems that include a solid-state impedance match with a multi-stage design that includes switched shunt capacitors arranged in a capacitor bank.

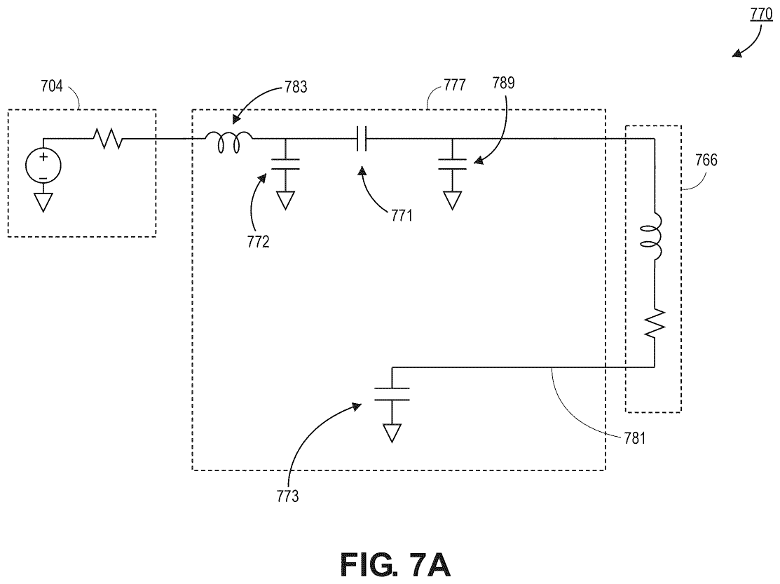

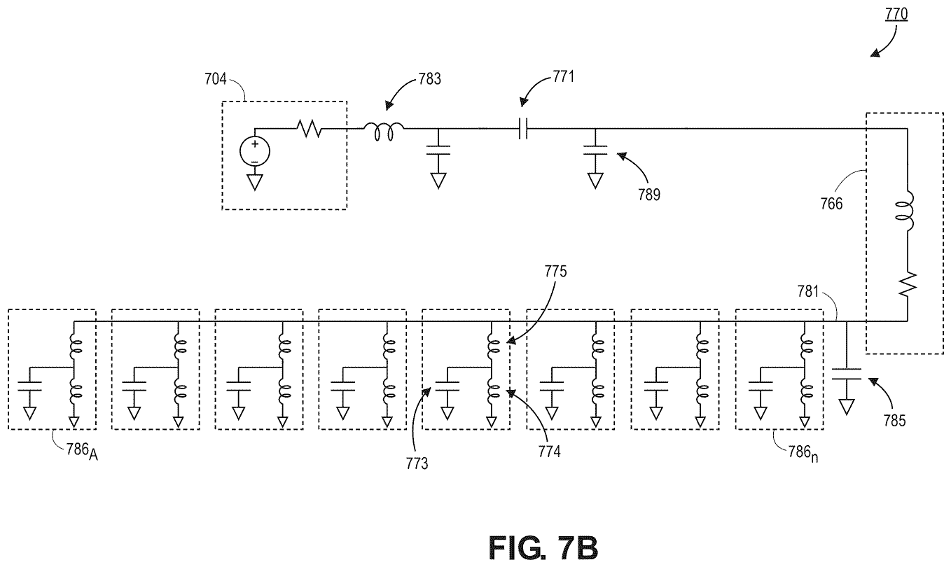

Referring now to FIGS. 7A and 7B, a series of circuit diagrams that depict an alternative RF matching configuration that uses switched shunt capacitors, such as those described in greater detail herein. Instead of providing a bank of switched shunt capacitors in series along an input RF line to the plasma load, embodiments may include adding one or more switched shunt capacitors along a return RF line from the plasma load back into the RF match. That is, embodiments may comprise a first switched shunt capacitor along the input RF line of the RF match and a second switched shunt capacitor (or bank of second switched shunt capacitors) along the return RF line of the RF match.

Referring now to FIG. 7A, a circuit diagram of a system 770 is shown, in accordance with an embodiment. As shown, the system 770 comprises an RF generator 704 that is electrically coupled to a plasma load 766 (generically represented as a an inductor and a resistor in series for simplicity) with an RF match 777 provided between the two. In an embodiment, an electrically conductive path that serves as the input line of the RF match may comprise a capacitor 771, a first switched shunt capacitor 772, and a second switched shunt capacitor 789. While shown schematically as a general capacitor, it is to be appreciated that one or both of the first switched shunt capacitor 772 or the second switched shunt capacitor 789 may be similar to any of the switched shunt capacitors described in greater detail herein, such as any of the switched shunt capacitor configurations shown in FIG. 2C or 2D. More particularly, the first switched shunt capacitor 772 and/or the second switched shunt capacitor 789 may comprise a half-bridge configuration. A fixed value inductor 783 may also be provided along the input line of the RF match. In an embodiment, a third switched shunt capacitor 773 may be provided on an electrically conductive path that functions as a return RF line 781 from the plasma load 766 back to the RF match 777. The third switched shunt capacitor 773 may be similar to any of the switched shunt capacitors described in greater detail herein, such as any of the switched shunt capacitor configurations shown in FIG. 2C or 2D. More particularly, the second switched shunt capacitor 773 may comprise a half-bridge configuration.

In the illustrated embodiment, the third switched shunt capacitor 773 is shown as a single capacitor. Though, in other embodiments, the third switched shunt capacitor 773 may comprise a bank of switched shunt capacitors 773 that allows for an adjustable capacitance to be provided to the circuit. For example, the bank of second switch shunt capacitors 773 may be similar to any of the capacitor banks described in greater detail herein. Similarly, the first switched shunt capacitor 772 and/or the second switched shunt capacitor 789 may also comprise a bank of capacitors.

In an embodiment, the electrically conductive input RF line and the electrically conductive return RF line 781 may be provided on a single board. Other embodiments may include the input RF line and the return RF line 781 on different boards. Similarly, the first switched shunt capacitor 772 and the third switched shunt capacitor 773 may be provided on the same board or on different boards.

Referring now to FIG. 7B, a circuit diagram of a system 770 for impedance matching a plasma load 766 is shown, in accordance with an additional embodiment. In an embodiment, the system 770 in FIG. 7B may be similar to the system 770 in FIG. 7A, with the exception of the bank of third capacitors 773. Instead of a plurality of third switched shunt capacitors 773, the third switched shunt capacitors 773 may each be coupled to the return RF line 781 by a transformer circuit 786. For example, the transformer circuit 786 may comprise an auto transformer with a first inductor 774 and a second inductor 775. Though, balanced transformer circuits may also be used in the transformer circuit 786 in other embodiments. The use of a transformer circuit 786 allows for the voltage seen by the third switched shunt capacitors 773 to be decreased. This may provide improved reliability for the third switched shunt capacitors 773 and/or allow for easier design of the system 770 since the third switched shunt capacitors 773 do not need to accommodate higher voltages. In an embodiment, a fixed value shunt capacitor 785, such as a vacuum capacitor, may also be provided on the return RF line from the plasma load 766.

In the illustrated embodiment, the bank of third switched shunt capacitors 773 comprises eight transformer circuits 786A-786n. Though, it is to be appreciated that any number of transformer circuits 786 and associated third switched shunt capacitors 773 may be used to provide a desired capacitance resolution to the RF match. In an embodiment, the bank of third switched shunt capacitors 773 may be provided on the same board of the RF match that the first switch shunt capacitor 771 is provided on. Though, in other embodiments, the first switched shunt capacitor 771 and the third switched shunt capacitors 773 may be provided on different boards of the RF match.

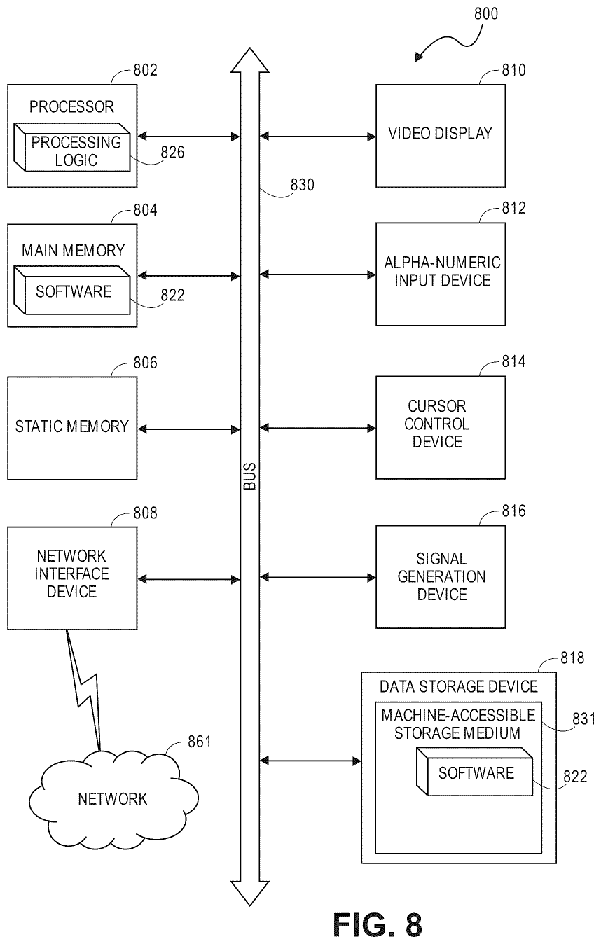

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
an electrically conductive path; and
a first switched shunt capacitor electrically coupled to the electrically conductive path, wherein the first switched shunt capacitor is configured to be switched on and off by a half-bridge circuit that comprises a first transistor and a second transistor, and wherein an RF choke is electrically coupled between the first transistor and the second transistor.

2. The apparatus of claim 1, further comprising:
a second electrically conductive path; and
a bank of second switched shunt capacitors electrically coupled to the second electrically conductive path, wherein each of the second switched shunt capacitors are configured to be switched on and off by a corresponding one of a plurality of second half-bridge circuits, wherein each of the plurality of second half-bridge circuits comprises a third transistor and a fourth transistor.

3. The apparatus of claim 2, wherein the electrically conductive path is an input RF line that is configured to be electrically coupled to an input of a plasma load, and the second electrically conductive path is a return RF line that is configured to be electrically coupled to an output of the plasma load.

4. The apparatus of claim 2, wherein the electrically conductive path and the second electrically conductive path are provided on a single board.

5. The apparatus of claim 2, wherein the electrically conductive path and the second electrically conductive path are provided on different boards.

6. The apparatus of claim 2, wherein the plurality of second half-bridge circuits each comprise a transformer circuit.

7. The apparatus of claim 6, wherein the transformer circuit is an auto transformer or a balanced transformer.

8. The apparatus of claim 2, wherein the bank of second switched shunt capacitors comprises eight or more second switched shunt capacitors.

9. The apparatus of claim 8, wherein the eight or more second switched shunt capacitors comprise two or more different capacitance values.

10. The apparatus of claim 2, further comprising:
a varactor electrically coupled to the electrically conductive path.

11. The apparatus of claim 1, wherein the first transistor and/or the second transistor comprise a bandgap of at least 1.5 eV.

12. An apparatus, comprising:
an RF generator; and
an impedance match electrically coupled to the RF generator, wherein the impedance match comprises:
a bank of switched shunt capacitors that are each configured to be controlled by a corresponding one of a plurality of circuits, wherein each of the plurality of circuits comprises a transistor with a bandgap of at least 1.5 eV.

13. The apparatus of claim 12, wherein the impedance match further comprises:
a second bank of the switched shunt capacitors that are each controlled by a corresponding one of a plurality of second circuits, wherein each of the plurality of second circuits comprises a second transistor with a bandgap of at least 1.5 eV.

14. The apparatus of claim 13, wherein the bank of the switched shunt capacitors and the second bank of the switched shunt capacitors are on different boards.

15. The apparatus of claim 12, wherein the RF generator and the impedance match are within a single enclosure.

16. The apparatus of claim 12, wherein the transistor is a SiC transistor.

17. The apparatus of claim 12, wherein each of the plurality of circuits are half-bridge circuits that are configured to charge and discharge the corresponding switch shunt capacitor.

18. The apparatus of claim 12, further comprising:
a first RF sensor between the RF generator and the impedance match; and
a second RF sensor between the impedance match and an output of the apparatus.

19. A varactor, comprising:
a first transistor with a first gate that is configured to be grounded;
a second transistor with a second gate that is configured to be grounded;
a first inductor electrically coupled to a first drain of the first transistor;
a second inductor electrically coupled to a second drain of the second transistor; and
a voltage source electrically coupled between the first inductor and the second inductor, wherein at least one of the first transistor or the second transistor comprises a bandgap that is at least 1.5 eV.

20. The varactor of claim 19, wherein the first inductor and the second inductor are inductively coupled to a third inductor, and wherein a first end of the third inductor is electrically coupled to ground and a second end of the third inductor is electrically coupled to an RF transmission line.
